(19) United States
(12) Patent Application Publication
(10) Pub. No.: US 2026/0097491 A1
(43) Pub. Date: Apr. 9, 2026

(54) TRAINING POLICY NEURAL NETWORKS IN SIMULATION USING SCENE SYNTHESIS MACHINE LEARNING MODELS

(71) Applicant: DeepMind Technologies Limited, London (GB)

(72) Inventors: Arunkumar Byravan, London (GB); Jan Humplik, London (GB); Leonard Hasenclever, London (GB); Arthur Karl Brussee, London (GB); Francesco Nori, London (GB)

(21) Appl. No.: 19/111,985

(22) PCT Filed: Sep. 15, 2023
(86) PCT No.: PCT/EP2023/075514

§ 371 Date: Mar. 14, 2025

Related U.S. Application Data
(60) Provisional application No. 63/407,129, filed on Sep. 15, 2022.

(51) Int. Cl. B25J 9/16; G06F 30/27

(52) U.S. Cl. CPC B25J 9/163; B25J 9/161; B25J 9/1697; G06F 30/27

(57) ABSTRACT

Methods, systems, and apparatus, including computer programs encoded on a computer storage medium, for training a policy neural network for use in controlling a robot. In particular, the policy neural network can be trained in simulation using images generated by a scene synthesis machine learning model.

### CROSS-REFERENCE TO RELATED APPLICATIONS

This application claims the benefit of priority to U.S. Provisional Application Ser. No. 63/407,129, filed Sep. 15, 2022, the entirety of which is incorporated herein by reference.

### BACKGROUND

Machine learning models receive an input and generate an output, e.g., a predicted output, based on the received input. Some machine learning models are parametric models and generate the output based on the received input and on values of the parameters of the model.

Some machine learning models are deep models that employ multiple layers of models to generate an output for a received input. For example, a deep neural network is a deep machine learning model that includes an output layer and one or more hidden layers that each apply a non-linear transformation to a received input to generate an output.

### SUMMARY

This specification generally describes a system implemented as computer programs on one or more computers in one or more locations that trains a policy neural network in simulation so that the policy neural network can be used to control a robot (also known as an agent) in the real-world.

Particular embodiments of the subject matter described in this specification can be implemented so as to realize one or more of the following advantages.

Training control policies in simulation and transferring them to real robots (sim2real) avoids many of the issues which make it challenging to learn directly in the real-world environment. Examples of these issues include difficulties in state estimation, risks to safety, and data efficiency. Additionally, training in simulation avoids wear and tear on the robot prior to actually deploying the robot for use in the environment.

However, creating accurate and realistic simulations is difficult and computationally expensive. In other words, generating scenes in a simulation while accurately modelling how robots sense and interact with the world is a difficult problem.

Reducing the gap between simulation and the real world, i.e., increasing the realism of the training, often involves the collection of small amounts of data followed by manual tuning, the use of established system identification tools, or more recently by learning neural network models of parts of the system. It is especially difficult to accurately model the geometry and visual appearance of unstructured scenes which affect how the robot makes contact with the world and how it senses its surroundings, e.g. when using a RGB camera. The need for modeling RGB cameras can partially be alleviated by using depth sensors or LiDARs which are easier to simulate and thus have a smaller sim2real gap, but such a compromise can restrict the set of tasks a robot can learn and restrict the range of robots to which these techniques are applicable. In general, existing approaches to photorealistic scene reconstruction and rendering work poorly in outdoor scenes and use specialized 3D scanning setups which are not widely available, hence limiting their applicability.

The described techniques can overcome these challenges by automatically generating simulation models for visually complex scenes with highly realistic rendering of RGB camera views and accurate geometry. In particular, the described techniques learn a scene synthesis model, e.g., a NeRF model, from as little as a single video of the real-world scene with which the robot will interact, and use the learned model in combination with a simulator of the physics of the environment to generate a combined simulation that has enough high enough fidelity to enable simulation-to-reality transfer of vision-guided control policies.

Thus, the described techniques enable zero-shot or few-shot transfer of a policy neural network from simulation to the real-world even when the robot operates in a visually complex scene and relies on observations that include images, e.g., RGB images of the environment, and needs to manipulate dynamic objects in order to successfully complete tasks in the real-world.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example action selection system.

FIG. 2 is a flow diagram of an example process for training the policy neural network

FIG. 3 shows an example of generating a combined simulation.

FIG. 4 is a flow diagram of an example process for generating training data in simulation.

FIG. 5 shows an example of generating an input observation image.

Like reference numbers and designations in the various drawings indicate like elements.

### DETAILED DESCRIPTION

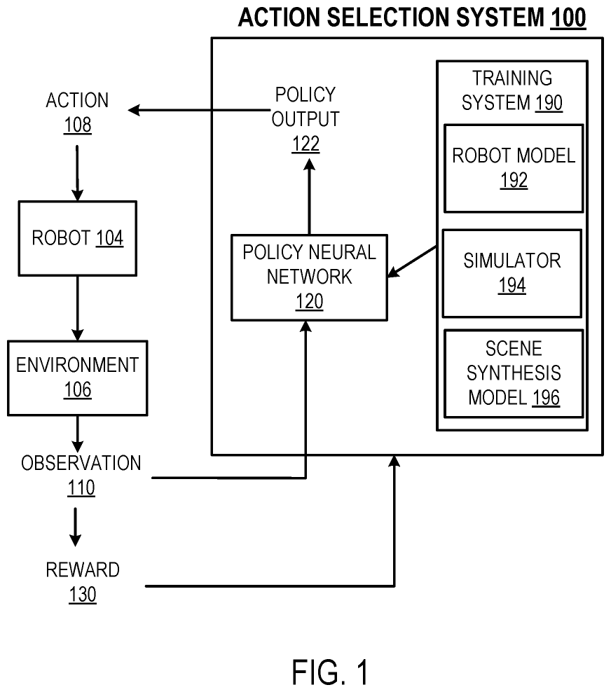

FIG. 1 shows an example action selection system 100. The action selection system 100 is an example of a system implemented as computer programs on one or more computers in one or more locations in which the systems, components, and techniques described below are implemented.

The action selection system 100 controls a robot 104 interacting with an environment 106 to accomplish a task by selecting actions 108 to be performed by the robot 104 at each of multiple time steps during the performance of an episode of the task.

The robot 104 can be any appropriate type of robot, e.g., a robotic arm, a humanoid robot, a quadruped robot, a vehicular robot, e.g., an autonomous vehicle, and so on.

As a general example, the task can include one or more of, e.g., navigating to a specified location in the environment, identifying a specific object in the environment, manipulating the specific object in a specified way, and so on.

More generally, the task is specified by received rewards, e.g., such that an episodic return is maximized when the task is successfully completed. Rewards and returns will be described in more detail below.

An “episode” of a task is a sequence of interactions during which the robot attempts to perform a single instance of the task starting from some starting state of the environment. In other words, each task episode begins with the environment being in an initial state, e.g., a fixed initial state or a randomly selected initial state, and ends when the robot has successfully completed the task or when some termination criterion is satisfied, e.g., the environment enters a state that has been designated as a terminal state or the robot performs a threshold number of actions without successfully completing the task.

At each time step during any given task episode, the system 100 receives an input observation 110 that includes an image captured by a camera of the robot 104 and causes the robot 104 to perform an action from a set of actions. For example, the set of actions can include a fixed number of actions or can be a continuous action space.

Optionally, the observation 110 can also include other data in addition to the image captured by the robot camera. For example, the observation 110 can include data from other sensors for the robot, e.g., data from a gyroscope of the robot, an accelerometer of the robot, or both. Additional data that can be included in the observation 110 is described in more detail below.

After the robot 104 performs the action 108, the environment 106 transitions into a new state and the system 100 receives a reward 130 from the environment 106.

Generally, the reward 130 is a scalar numerical value and characterizes the progress of the robot 104 towards completing the task.

As a particular example, the reward 130 can be a sparse binary reward that is zero unless the task is successfully completed as a result of the action being performed, i.e., is only non-zero, e.g., equal to one, if the task is successfully completed as a result of the action performed.

As another particular example, the reward 130 can be a dense reward that measures a progress of the robot towards completing the task as of individual observations received during the episode of attempting to perform the task, i.e., so that non-zero rewards can be and frequently are received before the task is successfully completed.

While performing any given task episode, the system 100 selects actions in order to attempt to maximize a return that is received over the course of the task episode.

That is, at each time step during the episode, the system 100 selects actions that attempt to maximize the return that will be received for the remainder of the task episode starting from the time step.

Generally, at any given time step, the return that will be received is a combination of the rewards that will be received at time steps that are after the given time step in the episode.

For example, at a time step t, the return can satisfy:

$${\sum }_{i} {γ}^{i - t - 1} {r}_{i} ,$$

where i ranges either over all of the time steps after t in the episode or for some fixed number of time steps after t within the episode, γ is a discount factor that is greater than zero and less than or equal to one, and rᵢ is the reward at time step i.

To control the robot, at each time step in the episode, the system 100 processes the observation using a policy neural network 120 to generate a policy output 122 that defines an action 108 for controlling the robot 104 in response to the observation 110.

In one example, the policy output 122 may include a respective numerical probability value for each action in a fixed set of actions. The system 102 can select the action, e.g., by sampling an action in accordance with the probability values for the action indices, or by selecting the action with the highest probability value.

In another example, the policy output may include a respective Q-value for each action in the fixed set. The system 102 can process the Q-values (e.g., using a soft-max function) to generate a respective probability value for each action, which can be used to select the action (as described earlier), or can select the action with the highest Q-value.

The Q-value for an action is an estimate of a return that would result from the robot performing the action in response to the current observation and thereafter selecting future actions performed by the robot in accordance with current values of the parameters of the policy neural network 120.

As another example, when the action space is continuous, the policy output can include parameters of a probability distribution over the continuous action space and the system can select the action by sampling from the probability distribution or by selecting the mean action. A continuous action space is one that contains an uncountable number of actions, i.e., where each action is represented as a vector having one or more dimensions and, for each dimension, the action vector can take any value that is within the range for the dimension and the only constraint is the precision of the numerical format used by the system 100.

As yet another example, when the action space is continuous the policy output can include a regressed action, i.e., a regressed vector representing an action from the continuous space, and the system 100 can select the regressed action as the action 108.

The policy neural network 120 can have any appropriate architecture that allows the policy neural network 120 to map an input that includes an observation image to a policy output.

As one example, the policy neural network 120 may include an “embedding” sub-network, a “core” sub-network, and one or more “selection” sub-networks. A sub-network of a neural network refers to a group of one or more neural network layers in the neural network.

When the observations are images, the embedding sub-network can be a convolutional sub-network, i.e., that includes one or more convolutional neural network layers, that is configured to process the observation for a time step.

The core sub-network can be a recurrent sub-network, e.g., that includes one or more long short-term memory (LSTM) neural network layers, or a Transformer neural network that is configured to process: (i) the output of the embedding sub-network and, optionally, (ii) data specifying any other information in the observation, e.g., lower-dimensional action data, the previous action, the most-recently received reward, and so on.

Each selection sub-network can be configured to process the output of the core sub-network to generate the corresponding output, i.e., a corresponding set of action scores or a corresponding parameter of a probability distribution. For example, each selection sub-network can be a multi-layer perceptron (MLP) or other fully-connected neural network. In some cases, the data specifying the other information in the observation can be provided as input to selection sub-network(s) instead of to the core sub-network.

The system 100 can then control the robot 104 by providing the action 108 defined by the policy output 122 as a control input for the robot 104.

Generally, the environment 106 is a real-world environment and the robot 104 interacts with the environment 106 to accomplish a goal, e.g., to locate an object of interest in the environment, to move an object of interest to a specified location in the environment, to physically manipulate an object of interest in the environment in a specified way, or to navigate to a specified destination in the environment.

In these implementations, the observations 110 may include, for example, one or more of images, object position data, and sensor data to capture observations as the robot interacts with the environment, for example sensor data from an image, distance, or position sensor or from an actuator.

For example, the observations may include data characterizing the current state of the robot, e.g., one or more of: joint position, joint velocity, joint force, torque or acceleration, for example gravity-compensated torque feedback, and global or relative pose of an item held by the robot.

As another example, the observations may similarly include one or more of the position, linear or angular velocity, force, torque or acceleration, and global or relative pose of one or more parts of the robot. The observations may be defined in 1, 2 or 3 dimensions, and may be absolute and/or relative observations.

The observations may also include, for example, data obtained by one of more sensor devices which sense a real-world environment; for example, sensed electronic signals such as motor current or a temperature signal; and/or image or video data for example from a camera or a LIDAR sensor, e.g., data from sensors of the robot or data from sensors that are located separately from the robot in the environment.

The observations can also include data characterizing the task, e.g., data specifying target states of the robot, e.g., target joint positions, velocities, forces or torques or higher-level states like coordinates of the robot or velocity of the robot, data specifying target states or locations or both of other objects in the environment, data specifying target locations in the environment, and so on.

The actions may be control inputs to control the robot, e.g., torques for the joints of the robot or higher-level control commands.

In other words, the control inputs can include for example, position, velocity, or force/torque/acceleration data for one or more joints or others parts of the robot. Control inputs may additionally or alternatively include electronic control data such as motor control data, or more generally data for controlling one or more electronic devices within the environment the control of which has an effect on the observed state of the environment.

Optionally, in any of the above implementations, the observation at any given time step may include data from a previous time step that may be beneficial in characterizing the environment, e.g., the action performed at the previous time step, the reward received at the previous time step, and so on.

Prior to using the policy neural network 120 to control the robot 104, a training system 190 trains the policy neural network 120.

More specifically, the system 190 trains the policy neural network 120 in simulation. That is, the system 190 trains the network 120 in a computer simulation of the environment 106.

For example, the system 190 can train the policy neural network 120 in simulation and then use the trained policy neural network 120 to control the robot 104 in the environment 106 without any further training, thereby performing zero shot transfer from simulation to the real-world (sim2real).

As another example, the system 190 can train the policy neural network 120 in simulation and then further train the policy neural network 120 while controlling the robot 104 in the environment 106, thereby performing few-shot transfer from simulation to the real-world.

In particular, when training the policy neural network 120 in simulation, the training system 190 uses a model 192 of the robot 104 and a simulator 194 that can accurately simulate the interaction of the robot 104 with the environment 106.

The model 192 of the robot 104 is data that specifies the configuration of the robot, e.g., the sensors of the robot and the physical and visual properties of the robot and that can be used by the simulator 194 to model the physics of the robot.

The simulator 194 can be any appropriate simulator software that can model the physics of the robot and any other dynamic objects in the environment. One example of such a simulator is the MuJoCo physics simulator that models the dynamics of the robot and the environment and accounts for collisions between objects. In general, the simulator 194 maintains a simulation state that defines the current states of any dynamic objects in the environment, e.g., the positions, velocities, accelerations, and so on, and maintains data specifying the physical and visual properties of the dynamic objects. The simulator 194 can update the simulator state to reflect changes to the environment, e.g., actions taken by the robot, the motion of other objections, collisions between objects or with static objects, and so on, by modeling the physics of the environment. The simulator 194 also includes a renderer that can render an image of an object given the current state of the object and the visual properties of the object.

The training system 190 also uses a scene synthesis machine learning model 196 as part of the training.

The scene synthesis machine learning model 196 is a model, e.g., a neural network, that is configured to receive a scene input that includes a camera viewpoint and to generate as output a synthetic image of the scene from the camera viewpoint.

Generally, during the training, the training system 190 can use the model 196 to generate synthetic images of the environment 106 for use in generating observations to be provided as input to the policy neural network 120 while using the simulator 194 to simulate the physics of the environment, e.g., the motion of objects in the environment and the effects on the robot and on the environment of actions selected by the policy neural network 120.

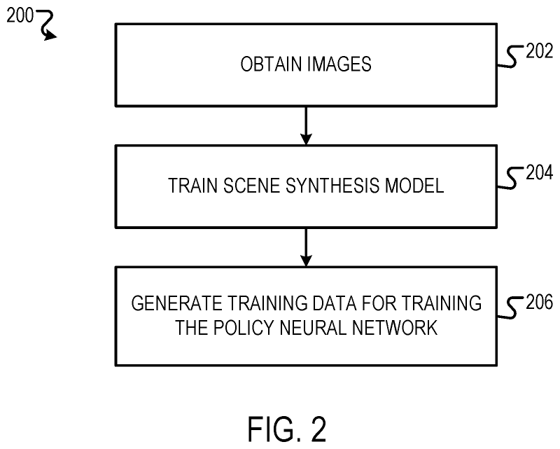

This training is described in more detail below with reference to FIGS. 2-4.

FIG. 2 is a flow diagram of an example process 200 for training the policy neural network. For convenience, the process 200 will be described as being performed by a system of one or more computers located in one or more locations. For example, an action selection system, e.g., the action selection system 100 of FIG. 1, appropriately programmed in accordance with this specification, can perform the process 200.

The system obtains a plurality of images of a scene in the real-world environment with which the robot will interact (step 202).

The system also obtains, for each image, corresponding camera data that includes a viewpoint of a camera that captured the image.

That is, the camera data includes camera pose information for each of the images and, more specifically, defines the camera intrinsics and extrinsics used to capture each of the images.

For example, the system can extract these images and the corresponding camera data from a video of the scene taken by the camera.

As one example, the system can obtain the video of the scene in the real-world environment and then extract images from the scene by selecting video frames from the video. As one example, the system can partition the video into partitions, e.g., equal partitions, and then select, from each partition, one or more images. For example, the system can select one or more least blurred images from each partition, e.g., by selecting the least blurred image from each partitioned based on the frame's variance of the Laplacian.

The system can then extract the camera data for the selected images.

As one example, the system can extract the camera data from meta data for the images that is available to the system.

As another example, the system can extract the camera data by applying a Structure-from-Motion (SfM) technique to the images. One example of an SfM package that can be used by the system to process the images in the video to extract the camera data is the COLMAP package.

The camera used to capture the images of the scene can generally be any appropriate camera device and does not need to be the same camera or have the same properties as the camera that the robot uses to capture observation images. Thus, the system can leverage a video taken by a generic camera, e.g., a generic mobile device camera, to extract the images and the camera data.

The system then trains a scene synthesis machine learning model using the plurality of images and the corresponding camera data (step 204).

As described above, the scene synthesis machine learning model is a machine learning model, e.g., a neural network, that is configured to receive a scene input that includes a camera viewpoint and to generate as output a synthetic image of the scene from the camera viewpoint.

Generally, the scene synthesis model can be any appropriate model that, after training, can generate synthetic images of the scene in the real-world environment from arbitrary viewpoints.

As one example, the scene synthesis model can be a Neural Radiance Fields (NeRF) model.

NeRF models represent radiance with a neural field that reproduces the geometric structure and appearance of a scene, allowing the use of backpropagation to reconstruct a set of input images. In particular, the NeRF model can predict the radiance and occupancy in space, i.e., the underlying space geometry, as part of rendering an image of a scene from a given viewpoint.

In particular, a NeRF model takes as input a camera pose and generates as output a synthetic image of the scene that appears as if the image was taken by a camera having the input camera pose. In some cases, the NeRF model also receives as input the camera intrinsics and generates as output a synthetic image that appears as if the image was taken by a camera having the input camera pose and having the input camera intrinsics.

The system can train any of a variety of NeRF models that make use of any of a variety of NeRF variants. Examples of such models and loss functions for training these models include those described in J. T. Barron, B. Mildenhall, D. Verbin, P. P. Srinivasan, and P. Hedman, “Mip-nerf 360: Unbounded anti-aliased neural radiance fields,” CoRR, vol. abs/2111.12077, 2021. T. Müller, A. Evans, C. Schied, and A. Keller, “Instant neural graphics primitives with a multiresolution hash encoding,” ACM Trans. Graph., vol. 41, pp. 102:1-102:15, July 2022 D. Verbin, P. Hedman, B. Mildenhall, T. E. Zickler, J. T. Barron, and P. P. Srinivasan, “Ref-nerf: Structured view-dependent appearance for neural radiance fields,” CoRR, vol. abs/2112.03907, 2021 J. T. Barron, B. Mildenhall, M. Tancik, P. Hedman, R. Martin-Brualla, and P. P. Srinivasan, “Mip-nerf: A multiscale representation for antialiasing neural radiance fields,” CoRR, vol. abs/2103.13415, 2021.

As a particular example, the system can make use of one or more of the below variants in order to improve the reconstruction quality and reconstructed geometry and to decrease the rendering time.

As one example, to avoid artifacts while rendering at low resolutions, the system can sample the average of the volume over a normal distribution.

As another example, the system can use a space squashing formulation to support large capture areas, as well as a separate ‘proposal’ network, and a ‘distortion’ loss that encourages compact representations.

As another example, to improve the reconstructed geometry, the system can optimise a separate specular and diffuse color.

As another example, to reduce latency, the system can implement a multi scale spatial hash grid approach. This can, for example, enabling rendering one frame in 6 ms on a V100 GPU.

As another example, the system can use any appropriate architecture for the multi-layer perceptrons (MLPs) that make up the NeRF model. For example, the system can use an architecture that adds a layer normalization before the final MLP layer, and use swish activations, e.g., rather than ReLU activations as in the original NeRF model.

As another example, the system can adapt the NeRF to allow sampling the radiance volume over a distribution. To achieve this, the system can blur training samples with a Gaussian blur with a random variance σblur∈[σmin, σmax], and provide Σ=Σsample*(1+(σblur−σmin)) as an extra input to the final MLP of the NeRF model. This augmentation allows the network to interpolate samples in scale-space and improves the reconstruction significantly at lower resolutions. For example, using this augmentation can result in ˜31.5 vs ˜35.4 average PSNR on an example held out image set.

Thus, the system trains a model that can generate synthetic images of the scene in the real-world environment.

The system then generates, using at least synthetic images generated by the scene synthesis machine learning model, training data for training the policy neural network (step 206).

That is, while collecting data during training data generation, the system generates, from synthetic images generated by the scene synthesis machine learning model, observations of scenes in a simulation of the environment being interacted with by a model of the robot. The system can then control the model of the robot within the simulation using outputs generated based on the observations. That is, the system uses the trained scene synthesis model to generate images of the state of the simulation of the environment that are then provided as input to the policy neural network.

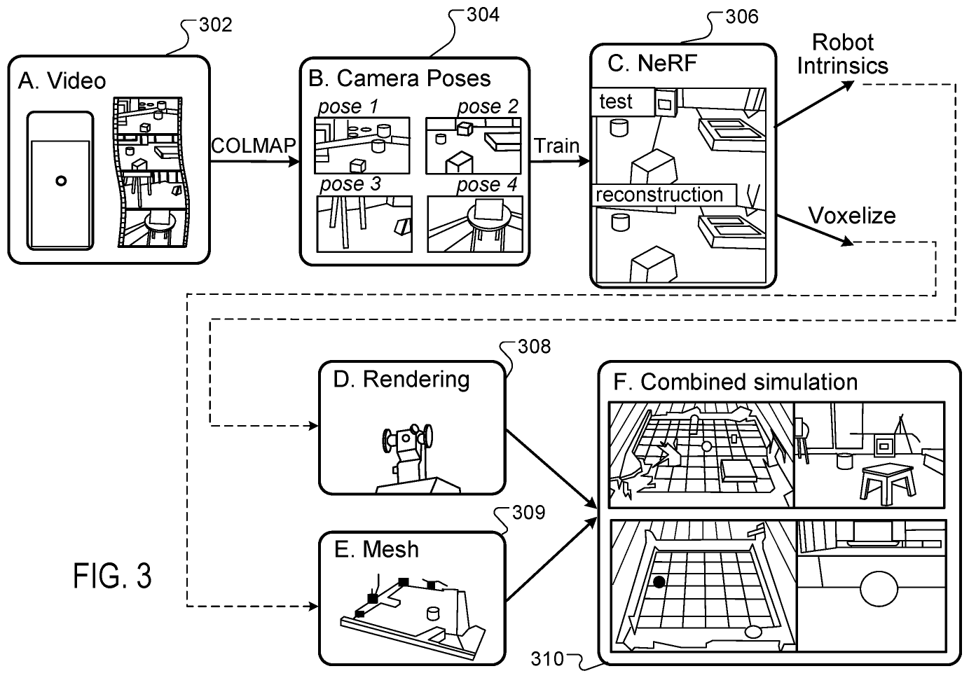

FIG. 3 shows an example 300 of generating a combined simulation 310 using a simulator and a scene synthesis machine learning model for use in generating training data for training the policy neural network.

As shown in FIG. 3, the system receives an input video 302 of a scene in a real-world environment. In the example of FIG. 3, the video is generated with a camera of a mobile device. More generally, however, the video can be generated using any appropriate camera device that can capture a video of a scene from multiple viewpoints.

The system applies COLMAP or a different SfM package to extract, from the video 302 a set of images with corresponding camera data that includes camera poses 304. The system then trains a scene synthesis machine learning model, e.g., a NeRF model 306, that generates new synthetic images of the scene from arbitrary viewpoints/camera poses.

Generally, as described above, the scene synthesis machine learning model receives as input a new viewpoint and camera intrinsics of a camera and generates as output a synthetic image of the scene captured from the new viewpoint and by a camera that has the input camera instrinsics.

When rendering 308 a given image of a scene in simulation, the system uses obtained camera intrinsics, e.g., focal length, distortion parameters, or both that are generated as a result of calibrating the camera of the robot. Thus, images rendered in simulation appear as if they were taken by the camera of the robot in the real-world environment. In other words, the system models the visuals of the environment using rendered images generated using the camera intrinsics of the robot camera.

The NeRF model 306 learns a function to predict the radiance and occupancy in space, i.e. the underlying scene geometry.

As part of generating the combined simulation 310, the system generates, using the trained scene synthesis model, a mesh of the scene. The system can then provide the mesh to the simulator for use in modeling collisions when updating the state of the simulation as part of the combined simulation 310.

In particular, the system can generate, from the trained synthesis model, an initial mesh in the first reference frame and then generate the mesh 309 by mapping vertices in the initial mesh from a first reference frame of the scene synthesis model to the world reference frame of the simulator.

More specifically, the system voxelizes the predicted occupancy generated by the trained scene synthesis model and computes an initial mesh using the predicted occupancy, e.g., via a marching cubes algorithm. As described in more detail below, the camera poses obtained from COLMAP, and hence also the collision mesh vertices, are expressed in an arbitrary reference frame (including an arbitrary scale). Therefore, the system estimates a rigid transformation and scale between this frame of reference and the simulator's world frame. For example, the system can compute the estimate by solving a least-squares optimization that constrains the normal vector to the dominant floor plane in the mesh to be aligned with the z-axis in the simulator. The system can then rotate the initial mesh around the z-axis to a desired alignment with the simulator's world frame and compute the relative scale between the NeRF and the world by comparing the size of an object within the initial mesh and the real world to generate the mesh 309.

The system can also replace the floor vertices in the mesh (which can have artifacts due to a lack of texture) with a flat plane. Optionally, for faster collision computation, the system crops the mesh 309 to the extents needed for simulation.

The system can then use the mesh 309 for collisions within the combined simulation 310.

The system can then combine the generated mesh with a model of the robot and any other dynamic objects in a physics simulator to generate the combined simulation 310. That is, while performing episodes of the task in the simulation in order to generate training data, the system generates composite scenes by using the physics simulator to model the states of the model of the robot and any other dynamic objects while (i) modeling the static aspects of the scene using images synthesized using the scene synthesis neural network and (ii) modeling collisions using the mesh 309.

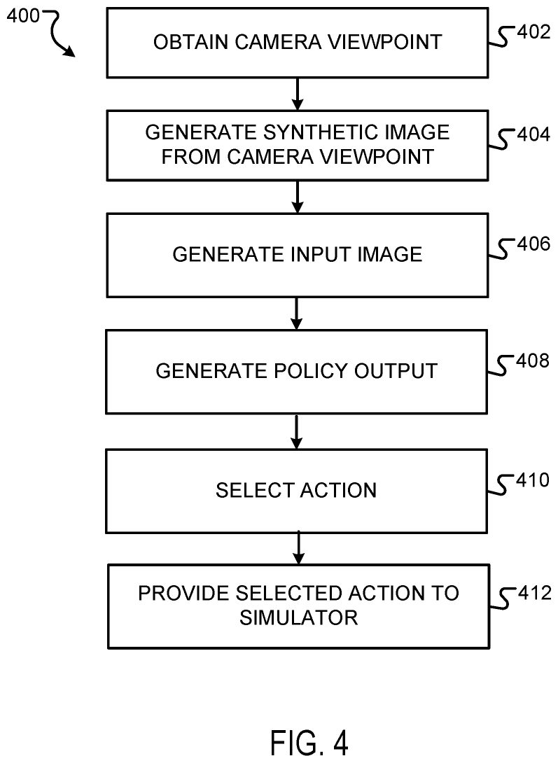

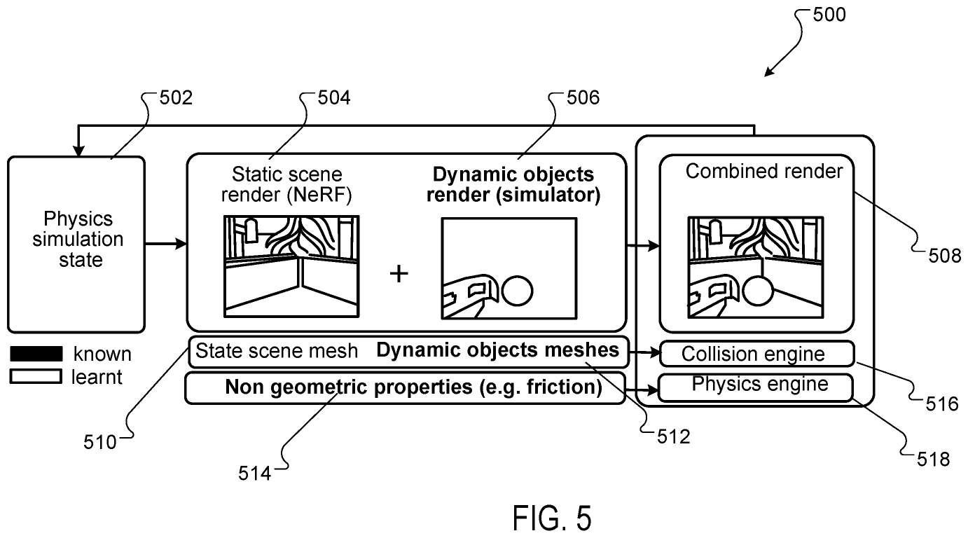

This is described in more detail below with reference to FIGS. 4 and 5.

FIG. 4 is a flow diagram of an example process 400 for generating training data for training the policy neural network. For convenience, the process 400 will be described as being performed by a system of one or more computers located in one or more locations. For example, an action selection system, e.g., the action selection system 100 of FIG. 1, appropriately programmed in accordance with this specification, can perform the process 400.

In particular, as part of generating the training data, the system controls the model of the robot in the simulation of the environment using the policy neural network at each of a plurality of time steps, e.g., to attempt to perform an episode of the task within the simulation.

At each time step, the system obtains, from a simulator, an input camera viewpoint based on a location of the robot camera at the time step within a state of the simulation of the real-world environment at the time step (step 402).

That is, as described above the simulator maintains a simulation state that is updated over time. At any given time step, the simulator state identifies the current state of the robot, e.g., including the current camera viewpoint of the camera of the robot. The system can use this current camera viewpoint as the input camera viewpoint for the time step.

In some implementations, the simulator operates in a different reference frame than the scene synthesis model, e.g., the scene synthesis model was trained on inputs specifying camera viewpoints in a different reference frame from the one used by the simulator. For example, the scene synthesis model can be configured to receive camera viewpoints in a first reference frame, e.g., an arbitrary reference frame generated by the SfM used by the system to estimate the camera data for the images in the training data while the simulator operates in a world reference frame.

In these implementations, as part of obtaining, from a simulator, an input camera viewpoint based on a location of the robot camera at the time step within the simulation of the real-world environment, the system receives, from the simulator, an initial camera viewpoint in the world reference frame; and generates the input camera viewpoint by mapping the initial camera viewpoint from the world reference frame to the first reference frame, e.g., by applying a rigid transformation and scale to the initial camera viewpoint to generate the camera viewpoint in the first reference frame as described above.

The system generates, using the scene synthesis model, a synthetic image of the scene from the input camera viewpoint (step 404).

That is, the system processes an input specifying the camera viewpoint using the scene synthesis model to generate as output a synthetic image of the scene from the input camera viewpoint. As described above, in some cases, the input to the scene synthesis model also includes data specifying the intrinsics of the camera that will capture the image. In these cases, the system provides, as part of the input, data specifying the intrinsics of the camera of the robot in order to maximize the alignment between images processed during simulation and images processed in the real-world, after training.

In other words, when the camera that captured the plurality of images used to train the scene synthesis model is different from the robot camera and the camera data used to train the scene synthesis model included camera parameters that specify intrinsics of the camera that captured the plurality of images, and the scene input further includes input camera parameters that specify intrinsics of an input camera that the synthetic image generated by the scene synthesis machine learning should match, the system generates each of the observations by providing scene inputs that include input camera parameters that specify intrinsics of the robot camera instead of intrinsics of the camera that captured the plurality of images.

The system generates an input image for the time step from at least the synthetic image of the scene (step 406).

Generally, the synthetic image of the scene will not include the robot or any dynamic objects that are in the scene as of the time point.

Therefore, to account for this, the system obtains, from the simulator, a respective rendering of one or more dynamic objects in the environment at the time step and generates the input image for the time step by combining the synthetic image of the scene and the respective renderings.

That is, the simulator renders the dynamic objects in the scene (including the robot) based on the respective states of these objects and respective visual properties of the objects as maintained by the simulator.

Generating the input image is described in more detail below with reference to FIG. 5.

The system processes an observation that includes the input image using the policy neural network to generate a policy output (step 408) and selects an action using the policy output (step 410), e.g., by selecting the action as described above or by applying an exploration policy to the policy output to select the action.

The system provides, to the simulator, the selected action for use in controlling the model of the robot to update the state of the simulation (step 412). That is, the system provides the selected action to the simulator, which uses the selected action to simulate the physics of the environment in order to update the state of the simulation, e.g., to update the state of the robot any other dynamic objects in the environment.

The system can then generate a respective training example for each of the time steps that includes the observation (which includes the input image) at the time step and the selected action at the time step.

Generally, the system will also receive, from the simulator, a respective reward for each time step and then includes the respective reward in the training example for the time step.

In some implementations, the system can regularize the received reward prior to using the reward for training, e.g., to improve the transfer of the learned policy neural network from simulation to the real-world. As one example, the system can use the following reward components as a regularization: 1. a constant penalty whenever the robot's yaw angular speed is larger than π rad s−1 to encourage the robot to turn slowly; 2. L2 regularization on joint angles towards a default standing pose; and, 3. when the robot is a humanoid or a quadruped, a walking reward encouraging the average of feet velocities in the robot's forward direction to be 0.3 ms⁻¹ These rewards encourage the policy neural network to learn gaits that transfer better, and also encourage better exploration for faster learning.

The system can train the policy neural network through reinforcement learning using any appropriate reinforcement learning technique, e.g., an off-policy reinforcement learning technique that uses an actor-critic framework. Examples of such techniques include policy gradient techniques, Q learning techniques, policy improvement techniques, and so on. As a particular example, the reinforcement learning can be a DMPO or MPO technique.

In some implementations, the system can use an asymmetric actor-critic setup for training in simulation where the critic, a separate neural network that is not evaluated on the robot, i.e., is not used after training, receives privileged information. As a specific example, the critic can share the same network structure as the actor but with the image encoder replaced with the simulation's ground truth state (robot/object poses and velocities).

For example, the system can store the generated training examples in a replay memory. The system can then sample batches of training examples from the replay memory and train the policy neural network on the sampled batch of training examples using the reinforcement learning technique.

In some implementations, the system can utilize data augmentation during training to improve the likelihood that the policy neural network will transfer successfully to the real-world. For example, while the NeRF model significantly reduces the sim2real gap with realistic scene renderings, the system can apply image augmentations to more reliably modulate image intensity properties such as brightness or gain. For example, the system can perform one or more of the following during training for images that are provided as input to the neural network: randomizing the brightness, randomizing the saturation, randomizing the hue, randomizing the contrast, or applying random translations to the image.

Additionally, in some implementations the system can employ domain randomization during training to improve the likelihood of successful transfer. Some examples of such randomizations now follow. As one example, the system can apply random pushes to the robot during training. As another example, the system can apply constant delays per episode, sampled uniformly from a specified range, e.g., in the range of 10 ms-50 ms, and, optionally, a jitter, to all simulated sensor data to reflect various latencies on the robot. As another example, at the beginning of each episode, the system can attach a random mass to a random position on the robot's torso and randomize the IMU's position on the torso. As another example, in tasks with a ball or other dynamic object, the system can additionally randomize the dynamic object's, e.g., the ball's, mass and radius at the start of each episode.

By repeatedly performing the process 400 to collect training data and repeatedly training on training examples sampled from the replay memory, the system trains the policy neural network to effectively control the model of the robot in the simulation.

After the training, the system can then use the policy neural network to control the robot in the real-world environment.

FIG. 5 shows an example 500 of generating an input image during training.

As seen in FIG. 5, the simulator maintains a physics simulation state 502. At any given time point, the system uses the state 502 to generate a static scene render 504 using the scene synthesis model while using the simulator to generate a dynamics objects render 506 that shows the current views of the dynamic objects in the environment.

The system then generates a combined render 508 from the static scene render 504 and the dynamic objects render 506. For example, the system can overlay the renderings of the dynamic objects over the static scene render 504 or combine the two renders in a different way.

The simulator also uses a static scene mesh 510 (generated using the scene synthesis model), dynamic object meshes 512, and non geometric properties (e.g., friction) 514 to generate inputs to a collision engine 516 and a physics engine 518 that update the simulation state 502, e.g., based on motion of dynamic objects and the action selected for the robot by the system.

As described above, the system can train the policy neural network to perform any of a variety of tasks. A few examples of such tasks now follow.

As one example, the task can be a navigation and obstacle avoidance task. For example, the task can be a point to point visual navigation task where the robot has to reach one or more goals (specified as (x,y) coordinates in the NeRF's frame of reference) while avoiding different obstacles in the environment, e.g., objects such as a large plant, a chair, and walls.

During training, the system can automatically compute the free areas of the scene using the NeRF's mesh and, during simulation, the system can randomly initialize the robot to a position and orientation within these free areas and choose targets in different parts of the space that the robot has to reach.

As one example, for this task, the reward for training can include one or more of the regularization terms described above and two task-specific terms: 1. A sparse bonus upon reaching the goal location; 2. a walking reward like the one used as a regularization but instead encouraging moving in the direction of the goal at a particular speed, e.g., 0.3 ms⁻¹. Episodes terminate whenever the robot's body parts other than the feet touch the scene's mesh. An episode to be successful if the robot gets to ≤25 cm of the target without falling & does not collide with any obstacles.

Another example of a task is a ball pushing task or, more generally, an object moving task in which the robot needs to move a specified object to a specified location of the environment. One example of such a task is a task in which the robot has to move a basketball to a corner of a workspace. The system can model the basketball as a simple orange ball. During training in simulation, each episode starts with the ball and robot randomly positioned. In some fraction, e.g., half, of all episodes, the system initializes the ball just in front of the robot to speed up learning.

As a reward, the system can use one or more of the regularization terms described above and two task-specific terms: 1. a reward for minimizing the distance between the ball and the goal region; and 2. a reward for minimizing the distance between the robot and the ball if the ball is not moving towards the goal.

Many other tasks that are specified by received rewards are possible.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework or a Jax framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what can be claimed, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claimed combination can be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

Aspects of the present disclosure may be as set out in the following clauses:
Clause 1. A method performed by one or more computers, the method comprising:
   obtaining a plurality of images of a scene in a real-world environment with which a robot will interact and, for each image, corresponding camera data comprising a viewpoint of a camera that captured the image;
   training a scene synthesis machine learning model using the plurality of images and the corresponding camera data, wherein the scene synthesis machine learning model is configured to receive a scene input that comprises a camera viewpoint and to generate as output a synthetic image of the scene from the camera viewpoint; and
   generating, using at least synthetic images generated by the scene synthesis machine learning model, training data for training a policy neural network for use in controlling the robot in the real-world environment to perform one or more tasks, wherein the policy neural network is configured to receive a policy input comprising an observation characterizing a current state of the environment and to generate as output a policy output defining an action to be performed by the robot in response to the observation, wherein the observation comprises an image of the environment captured by a robot camera of the robot, and wherein generating the training data comprises:
   generating, from synthetic images generated by the scene synthesis machine learning model, observations of scenes in a simulation of the environment being interacted with by a model of the robot.
Clause 2. The method of clause 1, further comprising:
   training the policy neural network on the training data.
Clause 3. The method of clause 2, further comprising:
   after the training, controlling the agent in the real-world environment using the policy neural network.
Clause 4. The method of any preceding clause, wherein obtaining the plurality of images comprises:
   obtaining a video of the scene in the real-world environment; and
   selecting, as the plurality of images, a plurality of the video frames from the video.
Clause 5. The method of clause 4, further comprising:
   determining the camera data for each of the plurality of images using Structure-from-Motion (SfM).
Clause 6. The method of any preceding clause, wherein generating the training data for training the policy neural network comprises:
   controlling the model of the robot in the simulation of the environment using the policy neural network at each of a plurality of time steps, comprising, at each time step:
      obtaining, from a simulator, an input camera viewpoint based on a location of the robot camera at the time step within a state of the simulation of the real-world environment at the time step;
      generating, using the scene synthesis model, a synthetic image of the scene from the input camera viewpoint;
      generating an input image for the time step from at least the synthetic image of the scene;
      processing an observation comprising the input image using the policy neural network to generate a policy output;
      selecting an action using the policy output; and
      providing, to the simulator, the selected action for use in controlling the model of the robot to update the state of the simulation; and
      generating a respective training example for each of the time steps that comprises the observation for the time step and the selected action for the time step.
Clause 7. The method of clause 6, wherein generating an input image for the time step from at least the synthetic image of the scene comprises:
   obtaining, from the simulator, a respective rendering of one or more dynamic objects in the environment at the time step; and
   generating the input image for the time step by combining the synthetic image of the scene and the respective renderings.
Clause 8. The method of clause 6 or clause 7, wherein the scene synthesis model is configured to receive camera viewpoints in a first reference frame and wherein the simulator operates in a world reference frame, and wherein obtaining, from a simulator, an input camera viewpoint based on a location of the robot camera at the time step within the simulation of the real-world environment comprises:
   receiving, from the simulator, an initial camera viewpoint in the world reference frame; and
   generating the input camera viewpoint by mapping the initial camera viewpoint from the world reference frame to the first reference frame.
Clause 9. The method of any one of clauses 6-8, further comprising:
   at each time step, receiving, from the simulator, a respective reward for each of the one or more tasks, wherein the training example includes the respective rewards.
Clause 10. The method of any preceding clause, further comprising:
   generating, using the trained scene synthesis model, a mesh of the scene; and
   providing the mesh to the simulator for use in modeling collisions when updating the state of the simulation.
Clause 11. The method of clause 10, when dependent on clause 8, wherein generating the mesh comprises:
   generating an initial mesh in the first reference frame; and
   generating the mesh by mapping vertices in the initial mesh from the first reference frame to the world reference frame of the simulator.
Clause 12. The method of any preceding clause, wherein the observation further comprises data from a gyroscope of the robot, an accelerometer of the robot, or both.
Clause 13. The method of any preceding clause when dependent on clause 2, wherein training the policy neural network comprises:
   training the policy neural network through reinforcement learning with domain randomization.
Clause 14. The method of any preceding clause, wherein the scene synthesis model is a Neural Radiance Field (NeRF) model.
Clause 15. The method of any preceding clause, wherein the camera that captured the plurality of images is different from the robot camera, wherein the camera data further comprises camera parameters that specify intrinsics of the camera that captured the plurality of images, wherein the scene input further comprises input camera parameters that specify intrinsics of an input camera that the synthetic image generated by the scene synthesis machine learning should match, and wherein generating, from synthetic images generated by the scene synthesis machine learning model, observations of scenes in a simulation of the environment being interacted with by a model of the robot comprises:
   generating each of the observations by providing scene inputs that include input camera parameters that specify intrinsics of the robot camera instead of intrinsics of the camera that captured the plurality of images.
Clause 16. A system comprising:
   one or more computers; and
   one or more storage devices communicatively coupled to the one or more computers, wherein the one or more storage devices store instructions that, when executed by the one or more computers, cause the one or more computers to perform the operations of the respective method of any one of clauses 1-15.
Clause 17. One or more non-transitory computer storage media storing instructions that when executed by one or more computers cause the one or more computers to perform the operations of the respective method of any one of clauses 1-15

1. A method performed by one or more computers, the method comprising:
obtaining a plurality of images of a scene in a real-world environment with which a robot will interact and, for each image, corresponding camera data comprising a viewpoint of a camera that captured the image;
training a scene synthesis machine learning model using the plurality of images and the corresponding camera data, wherein the scene synthesis machine learning model is configured to receive a scene input that comprises a camera viewpoint and to generate as output a synthetic image of the scene from the camera viewpoint; and
generating, using at least synthetic images generated by the scene synthesis machine learning model, training data for training a policy neural network for use in controlling the robot in the real-world environment to perform one or more tasks, wherein the policy neural network is configured to receive a policy input comprising an observation characterizing a current state of the environment and to generate as output a policy output defining an action to be performed by the robot in response to the observation, wherein the observation comprises an image of the environment captured by a robot camera of the robot, and wherein generating the training data comprises:
generating, from synthetic images generated by the scene synthesis machine learning model, observations of scenes in a simulation of the environment being interacted with by a model of the robot.

2. The method of claim 1, further comprising:
training the policy neural network on the training data.

3. The method of claim 2, further comprising:
after the training, controlling the robot in the real-world environment using the policy neural network.

4. The method of claim 1, wherein obtaining the plurality of images comprises:
obtaining a video of the scene in the real-world environment; and
selecting, as the plurality of images, a plurality of the video frames from the video.

5. The method of claim 4, further comprising:
determining the camera data for each of the plurality of images using Structure-from-Motion (SfM).

6. The method of claim 1, wherein generating the training data for training the policy neural network comprises:
controlling the model of the robot in the simulation of the environment using the policy neural network at each of a plurality of time steps, comprising, at each time step:
obtaining, from a simulator, an input camera viewpoint based on a location of the robot camera at the time step within a state of the simulation of the real-world environment at the time step;
generating, using the scene synthesis model, a synthetic image of the scene from the input camera viewpoint;
generating an input image for the time step from at least the synthetic image of the scene;
processing an observation comprising the input image using the policy neural network to generate a policy output;
selecting an action using the policy output; and
providing, to the simulator, the selected action for use in controlling the model of the robot to update the state of the simulation; and
generating a respective training example for each of the time steps that comprises the observation for the time step and the selected action for the time step.

7. The method of claim 6, wherein generating an input image for the time step from at least the synthetic image of the scene comprises:
obtaining, from the simulator, a respective rendering of one or more dynamic objects in the environment at the time step; and
generating the input image for the time step by combining the synthetic image of the scene and the respective renderings.

8. The method of claim 6, wherein the scene synthesis model is configured to receive camera viewpoints in a first reference frame and wherein the simulator operates in a world reference frame, and wherein obtaining, from a simulator, an input camera viewpoint based on a location of the robot camera at the time step within the simulation of the real-world environment comprises:
receiving, from the simulator, an initial camera viewpoint in the world reference frame; and
generating the input camera viewpoint by mapping the initial camera viewpoint from the world reference frame to the first reference frame.

9. The method of claim 6, further comprising:
at each time step, receiving, from the simulator, a respective reward for each of the one or more tasks, wherein the training example includes the respective rewards.

10. The method of claim 1, further comprising:
generating, using the trained scene synthesis model, a mesh of the scene; and
providing the mesh to the simulator for use in modeling collisions when updating the state of the simulation.

11. The method of claim 10 further comprising:
generating, using the trained scene synthesis model, a mesh of the scene, wherein generating the mesh comprises:
generating an initial mesh in the first reference frame; and
generating the mesh by mapping vertices in the initial mesh from the first reference frame to the world reference frame of the simulator; and
providing the mesh to the simulator for use in modeling collisions when updating the state of the simulation.

12. The method of claim 1, wherein the observation further comprises data from a gyroscope of the robot, an accelerometer of the robot, or both.

13. The method of claim 2, wherein training the policy neural network comprises:
training the policy neural network through reinforcement learning with domain randomization.

14. The method of claim 1, wherein the scene synthesis model is a Neural Radiance Field (NeRF) model.

15. The method of claim 1, wherein the camera that captured the plurality of images is different from the robot camera, wherein the camera data further comprises camera parameters that specify intrinsics of the camera that captured the plurality of images, wherein the scene input further comprises input camera parameters that specify intrinsics of an input camera that the synthetic image generated by the scene synthesis machine learning should match, and wherein generating, from synthetic images generated by the scene synthesis machine learning model, observations of scenes in a simulation of the environment being interacted with by a model of the robot comprises:
generating each of the observations by providing scene inputs that include input camera parameters that specify intrinsics of the robot camera instead of intrinsics of the camera that captured the plurality of images.

16. A system comprising:
one or more computers; and
one or more storage devices communicatively coupled to the one or more computers, wherein the one or more storage devices store instructions that, when executed by the one or more computers, cause the one or more computers to perform operations comprising:
obtaining a plurality of images of a scene in a real-world environment with which a robot will interact and, for each image, corresponding camera data comprising a viewpoint of a camera that captured the image;
training a scene synthesis machine learning model using the plurality of images and the corresponding camera data, wherein the scene synthesis machine learning model is configured to receive a scene input that comprises a camera viewpoint and to generate as output a synthetic image of the scene from the camera viewpoint; and
generating, using at least synthetic images generated by the scene synthesis machine learning model, training data for training a policy neural network for use in controlling the robot in the real-world environment to perform one or more tasks, wherein the policy neural network is configured to receive a policy input comprising an observation characterizing a current state of the environment and to generate as output a policy output defining an action to be performed by the robot in response to the observation, wherein the observation comprises an image of the environment captured by a robot camera of the robot, and wherein generating the training data comprises:
generating, from synthetic images generated by the scene synthesis machine learning model, observations of scenes in a simulation of the environment being interacted with by a model of the robot.

17. One or more non-transitory computer storage media storing instructions that when executed by one or more computers cause the one or more computers to perform operations comprising:
obtaining a plurality of images of a scene in a real-world environment with which a robot will interact and, for each image, corresponding camera data comprising a viewpoint of a camera that captured the image;
training a scene synthesis machine learning model using the plurality of images and the corresponding camera data, wherein the scene synthesis machine learning model is configured to receive a scene input that comprises a camera viewpoint and to generate as output a synthetic image of the scene from the camera viewpoint; and
generating, using at least synthetic images generated by the scene synthesis machine learning model, training data for training a policy neural network for use in controlling the robot in the real-world environment to perform one or more tasks, wherein the policy neural network is configured to receive a policy input comprising an observation characterizing a current state of the environment and to generate as output a policy output defining an action to be performed by the robot in response to the observation, wherein the observation comprises an image of the environment captured by a robot camera of the robot, and wherein generating the training data comprises:
generating, from synthetic images generated by the scene synthesis machine learning model, observations of scenes in a simulation of the environment being interacted with by a model of the robot.

18. The system of claim 16, wherein obtaining the plurality of images comprises:
obtaining a video of the scene in the real-world environment; and
selecting, as the plurality of images, a plurality of the video frames from the video.

19. The system of claim 18, the operations further comprising:
determining the camera data for each of the plurality of images using Structure-from-Motion (SfM).

20. The system of claim 16, wherein generating the training data for training the policy neural network comprises:
controlling the model of the robot in the simulation of the environment using the policy neural network at each of a plurality of time steps, comprising, at each time step:
obtaining, from a simulator, an input camera viewpoint based on a location of the robot camera at the time step within a state of the simulation of the real-world environment at the time step;
generating, using the scene synthesis model, a synthetic image of the scene from the input camera viewpoint;
generating an input image for the time step from at least the synthetic image of the scene;
processing an observation comprising the input image using the policy neural network to generate a policy output;
selecting an action using the policy output; and
providing, to the simulator, the selected action for use in controlling the model of the robot to update the state of the simulation; and
generating a respective training example for each of the time steps that comprises the observation for the time step and the selected action for the time step.
